(19) United States
(12) Patent Application Publication
(10) Pub. No.: US 2017/0062660 A1
(43) Pub. Date: Mar. 2, 2017

(54) NITRIDE SEMICONDUCTOR STACKED BODY AND SEMICONDUCTOR LIGHT EMITTING DEVICE

(71) Applicant: Kabushiki Kaisha Toshiba, Minato-ku (JP)

(72) Inventor: Hideto FURUYAMA, Yokohama (JP)

(73) Assignee: Kabushiki Kaisha Toshiba, Minato-ku (JP)

(21) Appl. No.: 15/059,808

(22) Filed: Mar. 3, 2016

(30) Foreign Application Priority Data
Aug. 25, 2015 (JP) 2015-166008

(51) Int. Cl. H01L 33/32; H01L 33/24

(52) U.S. Cl. CPC H01L 33/32; H01L 33/24

(57) ABSTRACT

According to one embodiment, the intermediate layer is provided between the p-side electron barrier layer and the p-type nitride semiconductor layer. The intermediate layer contains a nitride semiconductor. A bandgap of the intermediate layer becomes narrower continuously from the p-side electron barrier layer side toward the p-type nitride semiconductor layer side.

### CROSS-REFERENCE TO RELATED APPLICATION

This application is based upon and claims the benefit of priority from Japanese Patent Application No. 2015-166008, filed on Aug. 25, 2015; the entire contents of which are incorporated herein by reference.

### FIELD

Embodiments described herein relate generally to a nitride semiconductor stacked body and a semiconductor light emitting device.

### BACKGROUND

In recent years, light emitting devices using nitride semiconductors have become widely popularized; and the promotion of research and development to increase the luminous efficiency is continuing.

### BRIEF DESCRIPTION OF THE DRAWINGS

FIG. 1A is a schematic cross-sectional view of a nitride semiconductor stacked body of a first embodiment, and FIG. 1B is a schematic energy band diagram of the nitride semiconductor stacked body of the first embodiment;

FIG. 2A is a schematic cross-sectional view of a nitride semiconductor stacked body of a second embodiment, and FIG. 2B is a schematic energy band diagram of the nitride semiconductor stacked body of the second embodiment;

FIG. 3 is a schematic cross-sectional view of a semiconductor light emitting device of the embodiment; and

FIG. 4A shows an energy band diagram of a simulation of a nitride semiconductor stacked body of a reference example, FIG. 4B shows an electron density distribution in the simulation, and FIG. 4C shows a hole density distribution in the simulation.

### DETAILED DESCRIPTION

According to one embodiment, a nitride semiconductor stacked body includes an n-type nitride semiconductor layer, a p-type nitride semiconductor layer, an active layer, a p-side electron barrier layer, and an intermediate layer. The active layer is provided between the n-type nitride semiconductor layer and the p-type nitride semiconductor layer. The active layer contains a nitride semiconductor. The active layer includes a plurality of well layers and a plurality of barrier layers. One of the well layers is interposed between the barrier layers. Bandgaps of the barrier layers are wider than bandgaps of the well layers. The p-side electron barrier layer is provided between the active layer and the p-type nitride semiconductor layer. The p-side electron barrier layer contains a nitride semiconductor. A bandgap of the p-side electron barrier layer is wider than bandgaps of the active layer and the p-type nitride semiconductor layer. The intermediate layer is provided between the p-side electron barrier layer and the p-type nitride semiconductor layer. The intermediate layer contains a nitride semiconductor. A bandgap of the intermediate layer becomes narrower continuously from the p-side electron barrier layer side toward the p-type nitride semiconductor layer side.

Embodiments are described below with reference to the drawings. Note that in the drawings, the same components are denoted by the same reference numerals and signs.

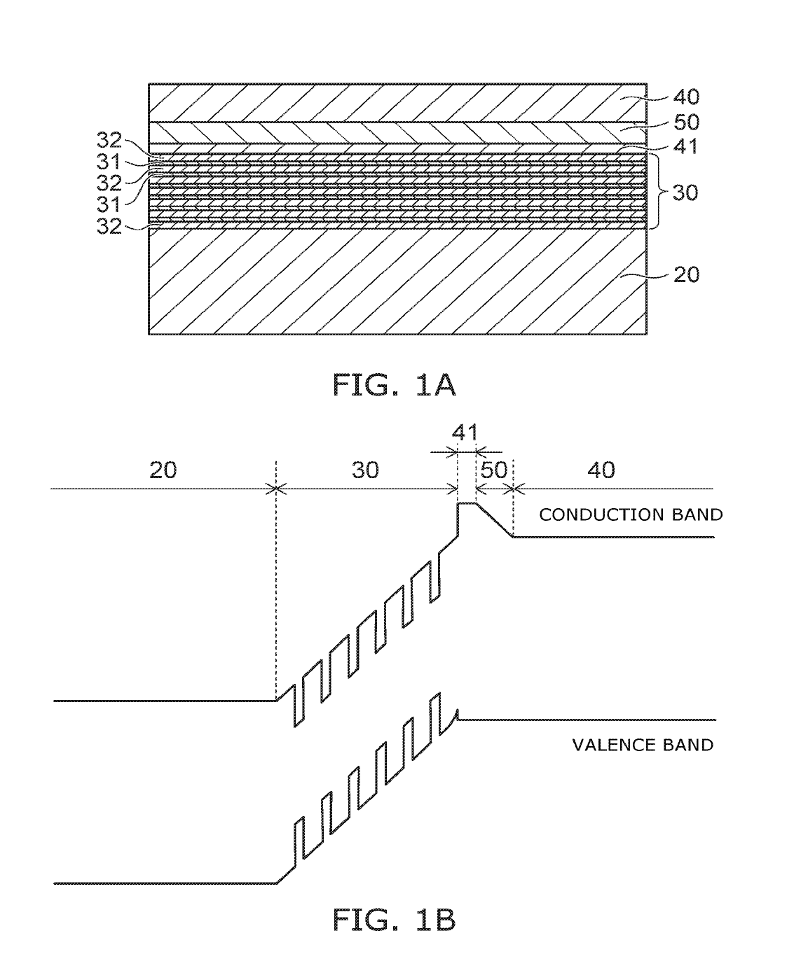

FIG. 1A is a schematic cross-sectional view of a nitride semiconductor stacked body of a first embodiment.

FIG. 1B is a schematic energy band diagram of the thermodynamic equilibrium state (the bias voltage being 0 V) of the nitride semiconductor stacked body of the first embodiment in which the piezoelectric effect is omitted.

In the specification, the nitride semiconductor is expressed by InₓAl_{y}Ga_{1-x-y}N (0≦x≦1, 0≦y≦1, and x+y≦1). “Nitride semiconductor” also includes the case where an impurity is added to control the conductivity type. A p-type layer is a layer containing a p-type impurity; and an n-type layer is a layer containing an n-type impurity.

The nitride semiconductor stacked body of the first embodiment (hereinbelow, also called simply the stacked body) includes an n-type clad layer 20, a p-type clad layer 40, an active layer 30, a p-side electron barrier layer 41, and an intermediate layer 50.

The n-type clad layer 20 is, for example, an n-type GaN layer and supplies electrons to the active layer 30 when a so-called p-n junction has a forward bias. The p-type clad layer 40 is, for example, a p-type GaN layer and supplies holes to the active layer 30 when the so-called p-n junction has the forward bias.

The active layer 30 has a multiple quantum well (MQW) structure in which multiple well layers 31 and multiple barrier layers 32 are stacked alternately. The number of stacks of the well layers 31 and the barrier layers 32 are arbitrary. The active layer 30 may include a single quantum well (SQW) having one well layer 31.

The bandgap of the well layer 31 is narrower than those of the n-type clad layer 20 and the p-type clad layer 40. The well layer 31 is interposed between the barrier layers 32 in the stacking direction; and the bandgap of the barrier layer 32 is wider than that of the well layer 31.

The well layer 31 contains, for example, undoped InₓGa₁₋ₓN (0<x<1). The barrier layer 32 contains, for example, undoped GaN and substantially does not contain In. Or, the barrier layer 32 contains In with a lower composition ratio than that of the well layer 31. Or, the barrier layer 32 contains, for example, undoped Al_{y}Ga_{1-y}N (0<y<1). The peak wavelength of the light emitted from the active layer 30 is, for example, not less than 360 nm and not more than 650 nm.

Here, “undoped” refers to an impurity not being added deliberately in the crystal growth. Conversely, the n-type or the p-type being recited refers to deliberately doping an impurity to control the conductivity type.

The p-side electron barrier layer 41 is provided between the active layer 30 and the p-type clad layer 40. The p-side electron barrier layer 41 is provided between the p-type clad layer 40 and the barrier layer 32 furthest on the p-type clad layer 40 side of the active layer 30.

The p-side electron barrier layer 41 is, for example, a p-type AlGaN layer having a bandgap that is wider than those of the p-type clad layer 40 and the barrier layer 32. The p-side electron barrier layer 41 suppresses the overflow of electrons from the active layer 30 toward the p-type clad layer 40 side.

The intermediate layer 50 is provided between the p-side electron barrier layer 41 and the p-type clad layer 40. The intermediate layer 50 has a bandgap that becomes narrower continuously from the p-side electron barrier layer 41 side toward the p-type clad layer 40 side.

The intermediate layer 50 is, for example, a layer containing gallium (Ga), nitrogen (N), and aluminum (Al) and is a layer containing a p-type impurity or is an undoped layer.

The Al composition ratio of the intermediate layer 50 is lower on the p-type clad layer 40 side than on the p-side electron barrier layer 41 side. The Al composition ratio of the intermediate layer 50 decreases gradually from the p-side electron barrier layer 41 side toward the p-type clad layer 40 side. For example, the Al concentration in the gas is reduced gradually in the epitaxial growth of the intermediate layer 50.

Or, the intermediate layer 50 is, for example, a layer containing gallium (Ga), nitrogen (N), aluminum (Al), and indium (In) and is a layer containing a p-type impurity or is an undoped layer.

The In composition ratio of the intermediate layer 50 is higher on the p-type clad layer 40 side than on the p-side electron barrier layer 41 side. The In composition ratio of the intermediate layer 50 increases gradually from the p-side electron barrier layer 41 side toward the p-type clad layer 40 side. For example, the In concentration in the gas is increased gradually in the epitaxial growth of the intermediate layer 50.

FIG. 4A is an energy band diagram of a reference example in the forward bias state of a nitride semiconductor stacked body that is generally used. In FIG. 4A, the electron quasi-Fermi level and the hole quasi-Fermi level are illustrated by single dot-dash lines.

FIG. 4A shows the results of a simulation including the piezoelectric effect.

FIG. 4B shows the electron density distribution in the simulation; and FIG. 4C shows the hole density distribution in the simulation.

In the stacked body of the reference example, the p-type doping causes the p-side electron barrier layer 41 and the p-type clad layer 40 to be up near the hole quasi-Fermi level; and the heterointerface of the p-side electron barrier layer 41 and the p-type clad layer 40, and a portion of the p-type clad layer 40 contacting the heterointerface push through the hole quasi-Fermi level and form a high density hole accumulation region. Then, in the forward bias due to the carrier injection, electrons are attracted toward the high density hole accumulation region to maintain the charge neutrality condition; the electrons excessively concentrate in the barrier layer 32 of the active layer 30 contacting the p-side electron barrier layer 41. The charge causes an effect equal to n-type doping; and the band of the barrier layer 32 of the active layer 30 contacting the p-side electron barrier layer 41 is modified and attracted toward the electron quasi-Fermi level side.

As a result, the excessive concentration of the electrons in the barrier layer 32 of the active layer 30 contacting the p-side electron barrier layer 41 is accelerated. Due to the electron concentration, an Auger effect (non-radiative carrier recombination) that is proportional to the third power of the electron density is accelerated; and a droop phenomenon is accelerated. The droop phenomenon is a phenomenon in which the luminous efficiency decreases as the injected current increases.

Conversely, according to the first embodiment shown in FIGS. 1A and 1B, the intermediate layer 50 that has a bandgap that becomes narrower continuously from the p-side electron barrier layer 41 side toward the p-type clad layer 40 side is provided between the p-side electron barrier layer 41 and the p-type clad layer 40. The bandgap does not change abruptly between the p-side electron barrier layer 41 and the p-type clad layer 40.

Such an intermediate layer 50 eliminates or relaxes the band discontinuity step of the valence band peak at the interface between the p-side electron barrier layer 41 and the p-type clad layer 40. The high density hole accumulation at the interface between the p-side electron barrier layer 41 and the p-type clad layer 40 can be suppressed. Therefore, the excessive concentration of the electrons at the interface between the active layer 30 and the p-side electron barrier layer 41 can be suppressed; and a droop phenomenon due to the Auger effect can be relaxed. It is possible to drastically improve the luminous efficiency in the high current injection region.

A second embodiment will now be described. The same components as those of the first embodiment recited above are marked with the same reference numerals, and a detailed description thereof is omitted.

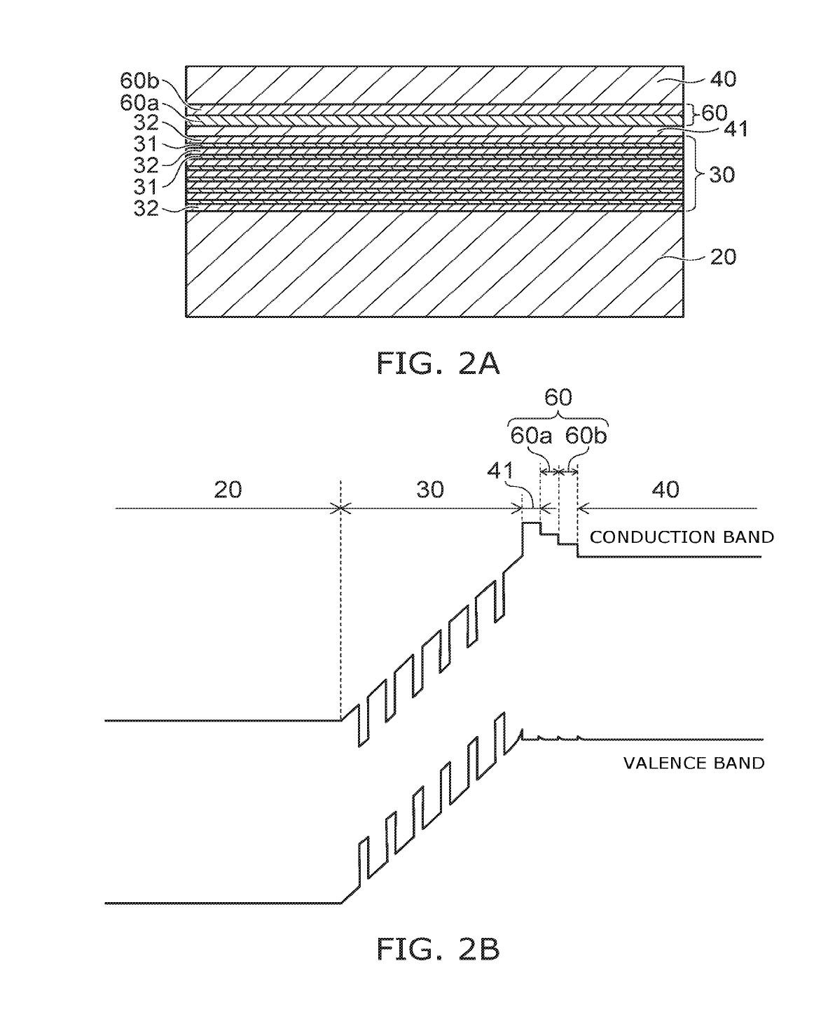

FIG. 2A is a schematic cross-sectional view of a nitride semiconductor stacked body of a second embodiment.

FIG. 2B is a schematic energy band diagram in the thermodynamic equilibrium state (the bias voltage being 0 V) of the nitride semiconductor stacked body of the second embodiment in which the piezoelectric effect is omitted.

An intermediate layer 60 is provided between the p-side electron barrier layer 41 and the p-type clad layer 40. The intermediate layer 60 is a single layer having an intermediate bandgap between those of the p-side electron barrier layer 41 and the p-type clad layer 40, or is a made of a multilayer semiconductor layer in which the bandgap becomes narrower in steps from the p-side electron barrier layer 41 side toward the p-type clad layer 40 side.

The intermediate layer 60 is a single layer or includes multiple layers 60a and 60b that have different bandgaps. The number of layers is arbitrary. The layer 60a is provided further on the p-side electron barrier layer 41 side than is the layer 60b and has a wider bandgap than the layer 60b. The layer 60b is provided further on the p-type clad layer 40 side than is the layer 60a and has a narrower bandgap than the layer 60a.

The layers 60a and 60b are, for example, layers containing gallium (Ga), nitrogen (N), and aluminum (Al) and are layers containing a p-type impurity or are undoped layers. The Al composition ratio of the layer 60b is lower than the Al composition ratio of the layer 60a.

Or, the layers 60a and 60b are, for example, layers containing gallium (Ga), nitrogen (N), aluminum (Al), and indium (In) and are layers containing a p-type impurity or are undoped layers. The In composition ratio of the layer 60b is higher than the In composition ratio of the layer 60a.

According to the second embodiment, the bandgap does not change abruptly between the p-side electron barrier layer 41 and the p-type clad layer 40 and becomes narrower in steps from the p-side electron barrier layer 41 side toward the p-type clad layer 40 side. Therefore, the band discontinuity amount at each interface becomes small.

This relaxes the band discontinuity step of the valence band peak at the interface between the p-side electron barrier layer 41 and the p-type clad layer 40. The high density hole accumulation of the interface between the p-side electron barrier layer 41 and the p-type clad layer 40 can be suppressed. Therefore, the excessive concentration of the electrons at the interface between the active layer 30 and the p-side electron barrier layer 41 can be suppressed; and the droop phenomenon due to the Auger effect can be relaxed.

In the embodiment described above, it is desirable for the maximum step of the band discontinuity of the valence band peak between the p-side electron barrier layer 41 and the p-type clad layer 40 to be 50 meV or less to suppress the high density accumulation of the holes between the p-side electron barrier layer 41 and the p-type clad layer 40. To realize this effect, the thicknesses of the intermediate layers 50 and 60 are 1 nm or more, and desirably not less than 2.5 nm.

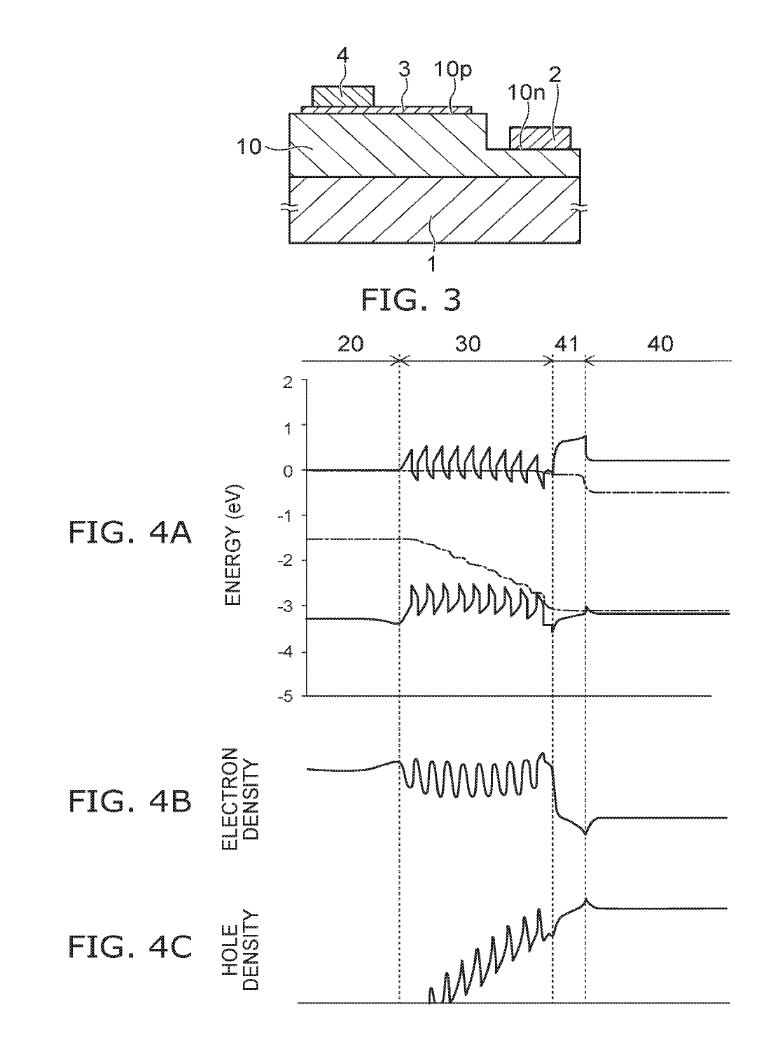

FIG. 3 is a schematic cross-sectional view of the semiconductor light emitting device of the embodiment. An LED (Light Emitting Diode) is shown as an example of the semiconductor light emitting device in FIG. 3.

The semiconductor light emitting device of the embodiment includes a nitride semiconductor layer 10. The nitride semiconductor layer 10 includes the nitride semiconductor stacked body of the embodiment described above.

For example, the nitride semiconductor layer 10 is formed on a substrate 1 by MOCVD (metal organic chemical vapor deposition) or MBE (molecular beam epitaxy). The substrate 1 may include, for example, a silicon substrate, a sapphire substrate, a SiC substrate, or a GaN substrate.

Other than the layers described above (the n-type clad layer, the active layer, the p-type clad layer, the p-side electron barrier layer, and the intermediate layer), the nitride semiconductor layer 10 may include a buffer layer that relaxes the mismatch of the lattice constants between the substrate 1 and the nitride semiconductors, contact layers for the electrodes, etc. Also, lattice defects may be reduced by forming a SLS (strained layer super lattice) buffer layer between the n-type clad layer and the substrate 1.

On the side opposite to the substrate 1, the nitride semiconductor layer 10 has a surface 10p of a p-type layer and a surface 10n of an n-type layer. An n-side electrode pad 2 is provided on the surface 10n of the n-type layer. A p-side electrode 3 (e.g., a Ag electrode or a transparent electrode of ITO (Indium Tin Oxide), etc.) is provided on the surface 10p of the p-type layer; and a p-side electrode pad 4 is provided on the p-side electrode 3.

The substrate 1 may remain as-is or may be removed. In the case of the former, it is desirable for the p-side electrode 3 to be a transparent electrode; and in the case of the latter, the p-side electrode 3 may be made of Ag and the light may be extracted from the surface where the substrate is removed. Also, in the case of the latter, the n-side electrode may be provided on the surface where the substrate is removed; or a configuration may be used in which a transparent electrode is formed as the n-side electrode, and the n-side electrode pad 2 is provided partially.

The LED that includes the nitride semiconductor stacked body of the embodiment described above has a high luminous efficiency. Or, the nitride semiconductor stacked body of the embodiment is not limited to an LED and is applicable to a LD (Laser Diode) as well.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A nitride semiconductor stacked body, comprising:
an n-type nitride semiconductor layer;
a p-type nitride semiconductor layer;
an active layer provided between the n-type nitride semiconductor layer and the p-type nitride semiconductor layer, the active layer containing a nitride semiconductor, the active layer including a plurality of well layers and a plurality of barrier layers, one of the well layers being interposed between the barrier layers, bandgaps of the barrier layers being wider than bandgaps of the well layers;
a p-side electron barrier layer provided between the active layer and the p-type nitride semiconductor layer, the p-side electron barrier layer containing a nitride semiconductor, a bandgap of the p-side electron barrier layer being wider than bandgaps of the active layer and the p-type nitride semiconductor layer; and
an intermediate layer provided between the p-side electron barrier layer and the p-type nitride semiconductor layer, the intermediate layer containing a nitride semiconductor, a bandgap of the intermediate layer becoming narrower continuously from the p-side electron barrier layer side toward the p-type nitride semiconductor layer side.

2. The stacked body according to claim 1, wherein a thickness of the intermediate layer is 1 nm or more.

3. The stacked body according to claim 2, wherein the thickness of the intermediate layer is 2.5 nm or more.

4. The stacked body according to claim 1, wherein
the intermediate layer contains gallium, nitrogen, and aluminum, and
an aluminum composition ratio on the p-type nitride semiconductor layer side of the intermediate layer is lower than an aluminum composition ratio on the p-side electron barrier layer side of the intermediate layer.

5. The stacked body according to claim 1, wherein
the intermediate layer contains gallium, nitrogen, aluminum, and indium, and
an indium composition ratio on the p-type nitride semiconductor layer side of the intermediate layer is higher than an indium composition ratio on the p-side electron barrier layer side of the intermediate layer.

6. The stacked body according to claim 1, wherein
the n-type nitride semiconductor layer contains n-type GaN,
the p-type nitride semiconductor layer contains p-type GaN, and
the p-side electron barrier layer contains p-type AlGaN.

7. A semiconductor light emitting device, comprising:
the nitride semiconductor stacked body according to claim 1;
an n-side electrode connected to the n-type nitride semiconductor layer; and
a p-side electrode connected to the p-type nitride semiconductor layer.

8. A nitride semiconductor stacked body, comprising:
an n-type nitride semiconductor layer;
a p-type nitride semiconductor layer; and
an active layer provided between the n-type nitride semiconductor layer and the p-type nitride semiconductor layer, the active layer containing a nitride semiconductor, the active layer including a plurality of well layers and a plurality of barrier layers, one of the well layers being interposed between the barrier layers, bandgaps of the barrier layers being wider than bandgaps of the well layers;
a p-side electron barrier layer provided between the active layer and the p-type nitride semiconductor layer, the p-side electron barrier layer containing a nitride semiconductor, a bandgap of the p-side electron barrier layer being wider than bandgaps of the active layer and the p-type nitride semiconductor layer; and
an intermediate layer provided between the p-side electron barrier layer and the p-type nitride semiconductor layer, the intermediate layer containing a nitride semiconductor, the intermediate layer being a single layer having an intermediate bandgap between the bandgaps of the p-side electron barrier layer and the p-type nitride semiconductor layer.

9. The stacked body according to claim 8, wherein a thickness of the intermediate layer is 1 nm or more.

10. The stacked body according to claim 9, wherein the thickness of the intermediate layer is 2.5 nm or more.

11. The stacked body according to claim 8, wherein
the n-type nitride semiconductor layer contains n-type GaN,
the p-type nitride semiconductor layer contains p-type GaN, and
the p-side electron barrier layer contains p-type AlGaN.

12. A semiconductor light emitting device, comprising:
the nitride semiconductor stacked body according to claim 8;
an n-side electrode connected to the n-type nitride semiconductor layer; and
a p-side electrode connected to the p-type nitride semiconductor layer.

13. A nitride semiconductor stacked body, comprising:
an n-type nitride semiconductor layer;
a p-type nitride semiconductor layer;
an active layer provided between the n-type nitride semiconductor layer and the p-type nitride semiconductor layer, the active layer containing a nitride semiconductor, the active layer including a plurality of well layers and a plurality of barrier layers, one of the well layers being interposed between the barrier layers, bandgaps of the barrier layer being wider than bandgaps of the well layer;
a p-side electron barrier layer provided between the active layer and the p-type nitride semiconductor layer, the p-side electron barrier layer containing a nitride semiconductor, a bandgap of the p-side electron barrier layer being wider than bandgaps of the active layer and the p-type nitride semiconductor layer; and
an intermediate layer provided between the p-side electron barrier layer and the p-type nitride semiconductor layer, the intermediate layer containing a nitride semiconductor, the intermediate layer being a multilayer intermediate layer having a bandgap becoming narrower in steps from the p-side electron barrier layer side toward the p-type nitride semiconductor layer side.

14. The stacked body according to claim 13, wherein a thickness of the intermediate layer is 1 nm or more.

15. The stacked body according to claim 14, wherein the thickness of the intermediate layer is 2.5 nm or more.

16. The stacked body according to claim 13, wherein
the intermediate layer contains gallium, nitrogen, and aluminum,
the intermediate layer includes a first layer and a second layer, the second layer being provided further on the p-type nitride semiconductor layer side than is the first layer; and
an aluminum composition ratio of the second layer is lower than an aluminum composition ratio of the first layer.

17. The stacked body according to claim 13, wherein
the intermediate layer contains gallium, nitrogen, aluminum, and indium,
the intermediate layer includes a first layer and a second layer, the second layer being provided further on the p-type nitride semiconductor layer side than is the first layer, and
an indium composition ratio of the second layer is higher than an indium composition ratio of the first layer.

18. The stacked body according to claim 13, wherein
the n-type nitride semiconductor layer contains n-type GaN,
the p-type nitride semiconductor layer contains p-type GaN, and
the p-side electron barrier layer contains p-type AlGaN.

19. A semiconductor light emitting device, comprising:
the nitride semiconductor stacked body according to claim 13;
an n-side electrode connected to the n-type nitride semiconductor layer; and
a p-side electrode connected to the p-type nitride semiconductor layer.
